(19) United States
(12) Patent Application Publication
(10) Pub. No.: US 2026/0215274 A1
(43) Pub. Date: Jul. 23, 2026

(54) PACKAGE STRUCTURE AND METHOD FOR FORMING THE SAME

(71) Applicant: Taiwan Semiconductor Manufacturing Company, Ltd., Hsinchu (TW)

(72) Inventor: Han Hsiang Liao, Hsinchu (TW)

(73) Assignee: Taiwan Semiconductor Manufacturing Company, Ltd., Hsinchu (TW)

(21) Appl. No.: 19/033,417

(22) Filed: Jan. 21, 2025

(51) Int. Cl. H01L 23/427; H01L 21/50; H01L 23/00; H01L 23/053; H01L 23/367

(52) U.S. Cl. CPC H10W 40/73; H10W 40/22; H10W 76/15; H10W 95/00; H10W 90/734

(57) ABSTRACT

A package structure includes a package substrate, a chip, and a lid structure. The chip is disposed on the package substrate, and the lid structure is disposed over the chip and bonded to the package substrate. The lid structure includes a ring portion, a lid portion, a vapor chamber, and an upper cover. The ring portion surrounds the chip. The lid portion is disposed on the ring portion to encapsulate the chip. The vapor chamber is disposed on the lid portion. The upper cover is disposed over the vapor chamber. At least one trench is formed on a top of the upper cover or outer sidewalls of the ring portion.

### BACKGROUND

The semiconductor integrated circuit (IC) industry has experienced rapid growth. Over the course of this growth, functional density of the devices has generally increased by the device feature size. This scaling down process generally provides benefits by increasing production efficiency, lower costs, and/or improving performance. Such scaling down has also increased the complexities of processing and manufacturing ICs and, for these advances to be realized similar developments in IC fabrication are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a package structure in accordance with some embodiments of the present disclosure.

FIG. 2 illustrates a three-dimensional view of a lid structure of the package structure in accordance with some embodiments of the present disclosure.

FIG. 3A illustrates a top view of a lid structure of the package structure in accordance with some embodiments of the present disclosure.

FIG. 3B illustrates a top view of a lid structure of the package structure in accordance with some embodiments of the present disclosure.

FIG. 4A illustrates a top view of a lid structure of the package structure in accordance with some embodiments of the present disclosure.

FIG. 4B illustrates a top view of a lid structure of the package structure in accordance with some embodiments of the present disclosure.

FIG. 5 illustrates a cross-sectional view of a package structure in accordance with some embodiments of the present disclosure.

FIG. 6 illustrates a three-dimensional view of a lid structure of the package structure in accordance with some embodiments of the present disclosure.

FIG. 7 illustrates a cross-sectional view of a package structure in accordance with some embodiments of the present disclosure.

FIG. 8A illustrates a side view of a lid structure of the package structure in accordance with some embodiments of the present disclosure.

FIG. 8B illustrates a side view of a lid structure of the package structure in accordance with some embodiments of the present disclosure.

FIG. 9 illustrates a three-dimensional view of a lid structure of the package structure in accordance with some embodiments of the present disclosure.

FIG. 10 is a flowchart illustrating a method for forming a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein relate to a package structure including a vapor chamber (VC) lid for high power applications such as chip-on-wafer-on-substrate (CoWoS) applications using high performance processors (e.g., graphics processing unit (GPU)) and a method for forming the same. In an embodiment, the VC lid may be used to provide a distributed heat transfer from the chip-on-wafer towards outside. In the VC lid, a vapor chamber is sealed therein and contains an evaporating and condensing fluid such as a two-phase vaporizable fluid for improving heat dissipation. However, since the thickness of the VC lid is too thick to release stress, the VC lid suffers an adhesive delamination risk. In particular, since thick VC lid is hard to deform, the stress is concentrated to the adhesive portion between the bottom of the VC lid and the substrate, causing the delamination issue of adhesive when the temperature changes. In contrast with previous structure, at least some embodiments provide one or more trenches to solve the problem that it is hard to deform for lid leading adhesive delamination risk.

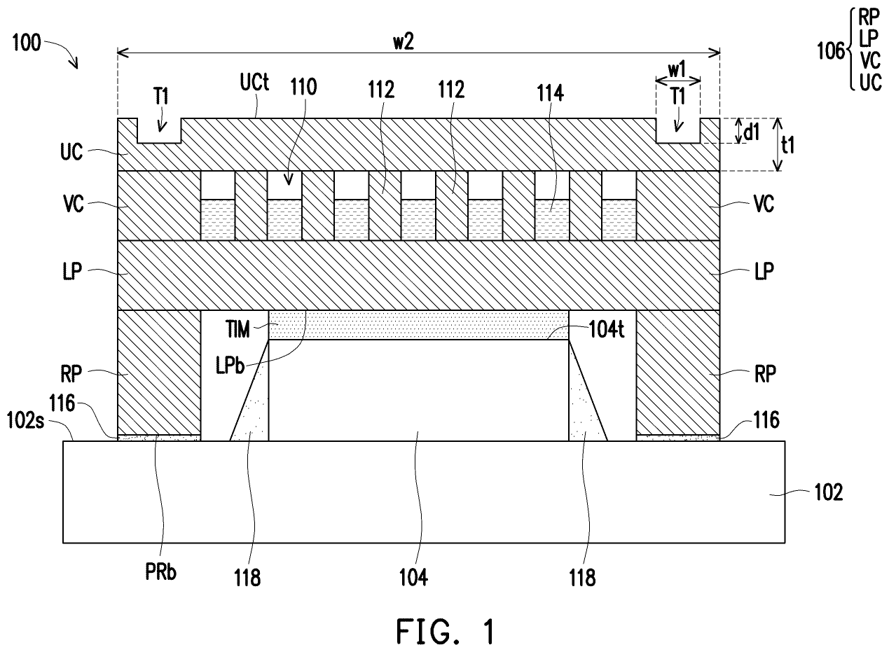

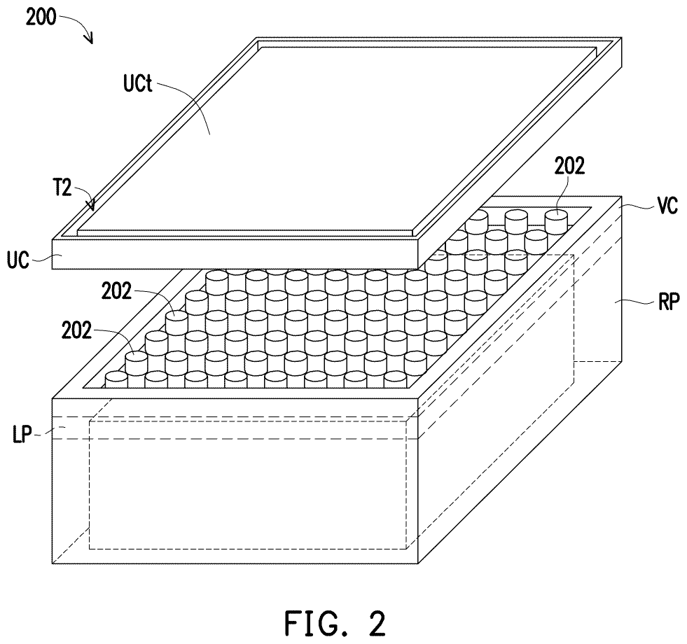

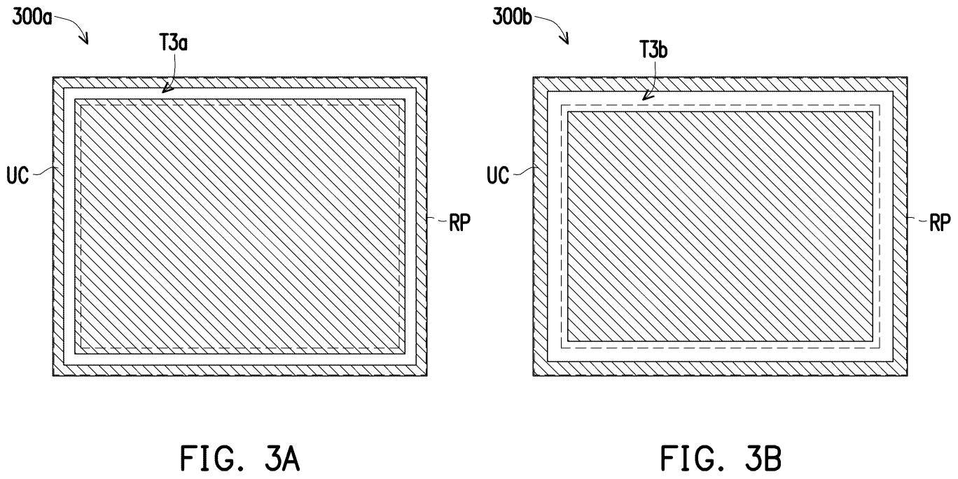

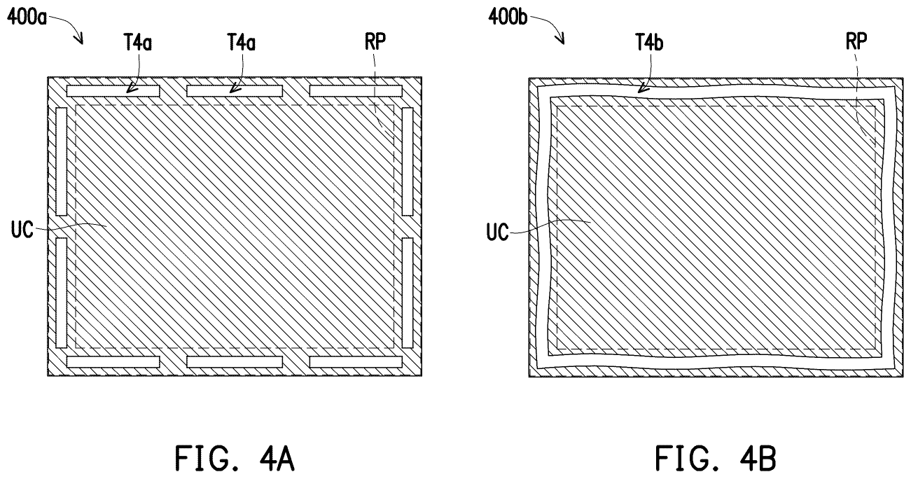

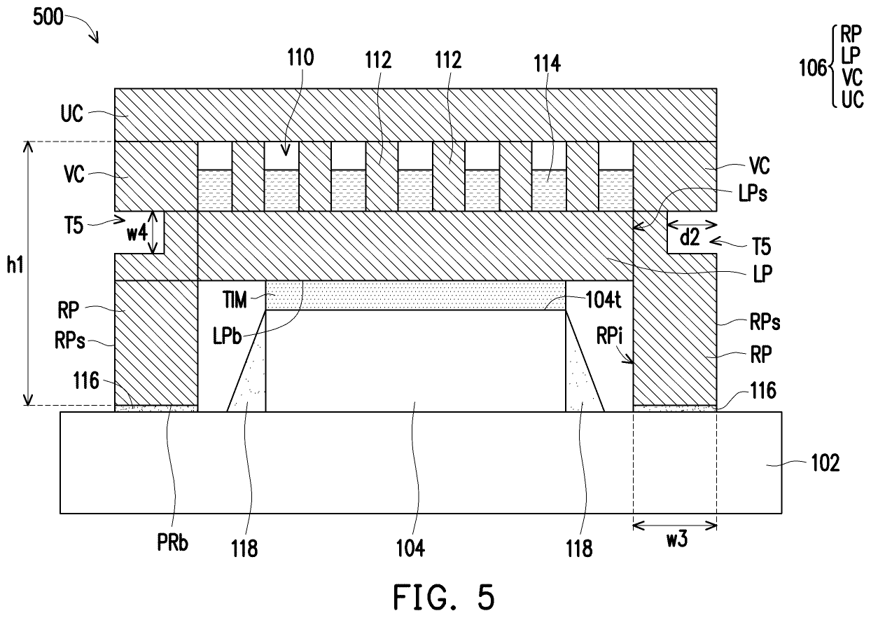

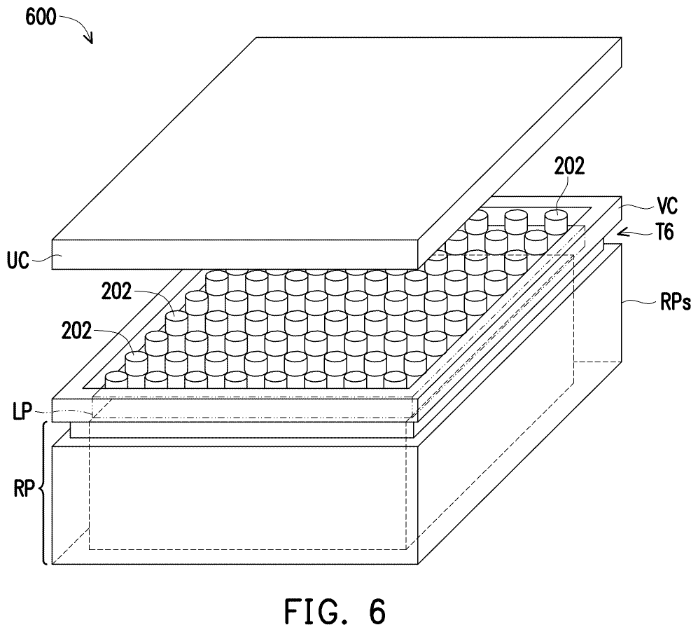

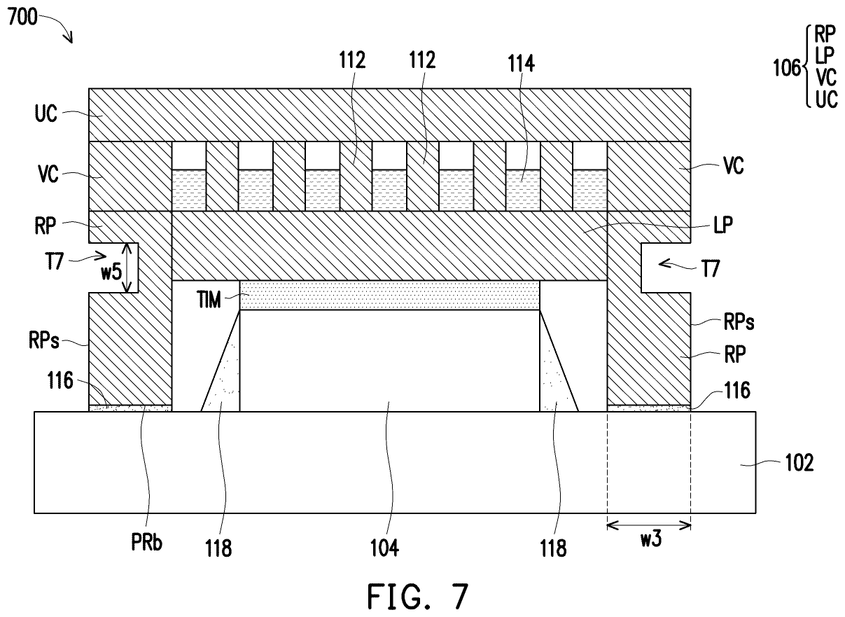

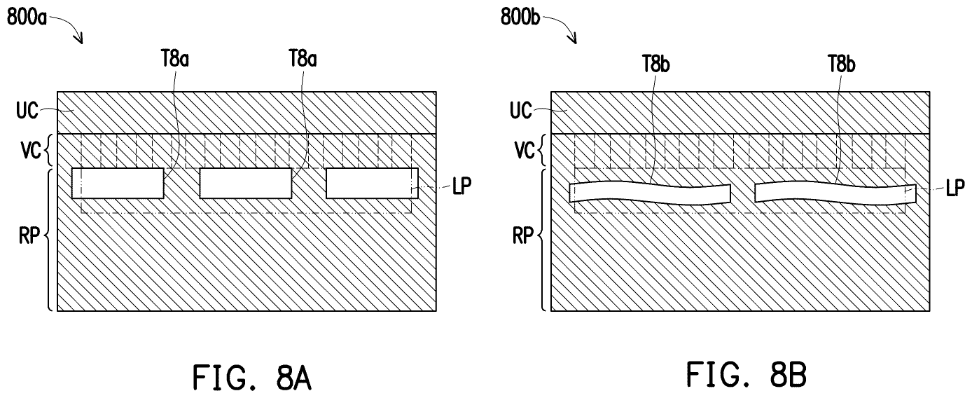

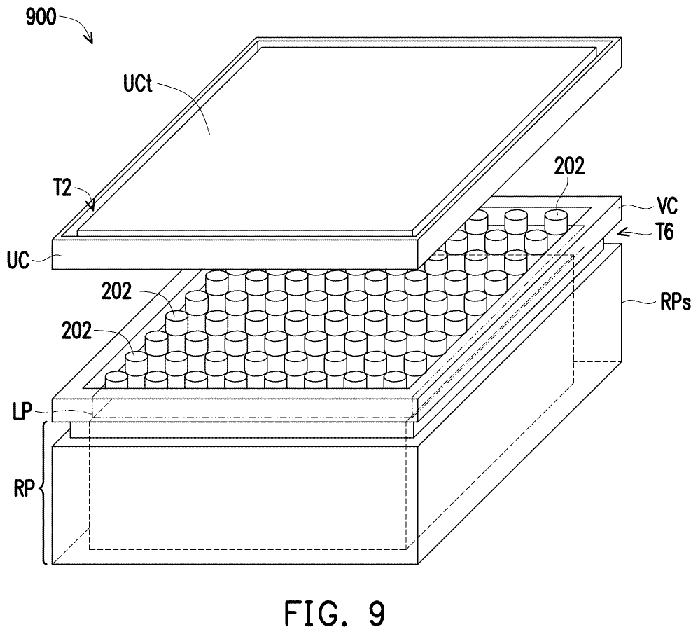

The various aspects of the present disclosure will now be discussed below with reference to FIGS. 1-9. In more detail, FIG. 1 illustrates a cross-sectional view of a package structure according to embodiments of the present disclosure. FIG. 2 illustrates a three-dimensional view of a lid structure of the package structure according to embodiments of the present disclosure. FIGS. 3A, 3B, 4A and 4B illustrate top views of a lid structure of the package structure according to embodiments of the present disclosure. FIG. 5 illustrates a cross-sectional view of a package structure according to embodiments of the present disclosure. FIG. 6 illustrates a three-dimensional view of a lid structure of the package structure according to embodiments of the present disclosure. FIG. 7 illustrates a cross-sectional view of a package structure according to embodiments of the present disclosure. FIGS. 8A and 8B illustrate side views of a lid structure of the package structure according to embodiments of the present disclosure. FIG. 9 is a flowchart illustrating a method for forming a package structure according to various aspects of the present disclosure.

Referring now to FIG. 1, a package structure 100 includes a package substrate 102, a chip 104, and a lid structure 106. The chip 104 is disposed on the package substrate 102, and the lid structure 106 is disposed over the chip 104 and bonded to the package substrate 102. In some embodiments, the package substrate 102 is a printed circuit board (PCB) or the like. In some embodiments, the package substrate 102 is referred to as a circuit substrate. In some embodiments, the package substrate 102 includes a plurality of routing patterns (not shown) embedded therein, and the routing patterns are interconnected with one another. In some embodiments, some of the routing patterns are exposed at a top surface 102s of the package substrate 102. In some embodiments, the chip 104 is mounted on the exposed routing patterns of the package substrate 102.

In some embodiments, the package substrate 102 includes a substrate core (not shown), which may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core may be a SOI substrate. Generally, an SOI substrate includes a layer of a semiconductor material such as epitaxial silicon, germanium, silicon germanium, SOI, SGOI, or combinations thereof. In another embodiment, the substrate core is an insulating core such as a fiberglass reinforced resin core. Alternatives for the core material include bismaleimide-triazine (BT) resin, or the like. Build up films such as Ajinomoto build-up film (ABF) or other laminates may be used for the substrate core. The substrate core of the package substrate 102 may also include metallization layers and vias, and bond pads over the metallization layers and vias. The metallization layers may be formed as functional circuitry. The metallization layers may be formed of alternating layers of conductive lines and conductive vias, wherein the conductive vias interconnect the layers of the conductive lines. The conductive lines and the conductive vias may be formed of copper and embedded in dielectric material (e.g., low-k dielectric material). The metallization layers may be formed through any suitable process (such as deposition, damascene, or the like).

In some embodiments, the chip 104 may be a chip-on-wafer (CoW) wafer which is bonded to the package substrate 102. In some embodiments, the chip 104 may be an integrated circuit die such as a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). In some embodiments, the chip 104 may include a semiconductor substrate, an interconnect structure, die connectors, and the like.

The lid structure 106 includes a ring portion RP, a lid portion LP, a vapor chamber VC, and an upper cover UC. The ring portion RP surrounds the chip 104. The lid portion LP is disposed on the ring portion RP to encapsulate the chip 104. The vapor chamber VC is disposed on the lid portion LP. The upper cover UP is disposed over the vapor chamber VC. At least one trench T1 is formed in the upper cover UC and extends from a top surface UCt of the upper cover UC. In some embodiments, the lid structure 106 (e.g., the ring portion RP, the lid portion LP, the vapor chamber VC, and the upper cover UC) comprises a material such as copper, copper alloy, copper tungsten (CuW), or aluminum-silicon-carbide (AlSiC). Other suitable thermally conductive materials and/or thermally insulating materials may also be used. In some embodiments, the trench T1 is directly over the ring portion RP of the lid structure 106. In some embodiments, the trench T1 may be a continuous trench or a plurality of discontinuous trenches.

In some embodiments, a ratio of a depth d1 of the trench T1 to a thickness t1 of the upper cover UC is in a range from 0.5 to 1. In some embodiments, a lower limit of the ratio of the depth d1 to the thickness t1 is 0.55, 0.6, 0.65, 0.7, and so on. In some embodiments, an upper limit of the ratio of the depth d1 to the thickness t1 is 0.95, 0.9, 0.85, 0.8, and so on.

In some embodiments, a ratio of a width w1 of the trench T1 to a width w2 of the upper cover UC is in a range from 0.05 to 0.3. In some embodiments, a lower limit of the ratio of the width w1 to the width w2 is 0.06, 0.07, 0.08, 0.09, and so on. In some embodiments, an upper limit of the ratio of the width w1 to the width w2 is 0.29, 0.28, 0.27, 0.26, and so on.

In some embodiments, the vapor chamber VC of the lid structure 106 can enhance heat dissipation from the chip 104. In some embodiments, the vapor chamber VC encloses, hermetically seals, and defines a cavity within inner walls of the vapor chamber VC to provide an internal chamber 110 within the vapor chamber VC. As illustrated, many columns 112 are disposed in the vapor chamber VC to provide extra structural support, such as at elevated temperatures. In some embodiments, a fluid 114 is contained in the vapor chamber VC of the lid structure 106. In some embodiments, the fluid 114 is an evaporating and condensing fluid such as a two-phase vaporizable fluid for improving heat dissipation. In addition, the columns 112 may prevent the fluid 114 within from boiling. In some embodiments, the fluid 114 is a liquid that possesses a relatively high latent heat of vaporization in order to disperse heat away from the chip 104. While the vapor chamber VC accumulates, transfers, and expels heat away from the chip 104, the fluid 114 contained in the vapor chamber VC is heated and vaporizes. The vapor of the fluid 114 then spreads and comes into contact with a bottom surface of the upper cover UC, heat is expelled through the cooler surfaces of the upper cover UC, and the vapor condenses back to its liquid form of the fluid 114. Once condensed, the fluid 114 reflows to the internal chamber 110 within the vapor chamber VC. In some embodiments, the columns 112 in the vapor chamber VC may be arranged in an array. The vapor chamber VC and the columns 112 comprise materials that possess a high thermal conductivity and a low coefficient of thermal expansion (CTE). In some embodiments, the vapor chamber VC and the columns 112 are integrally formed with a single material.

In some embodiments, a thermal interface material TIM is disposed between the lid portion LP of the lid structure 106 and a top 104t of the chip 104. The thermal interface material TIM serves to dissipate heat generated by the chip 104 to the attached lid structure 106. In some embodiments, the thermal interface material TIM may be formed of a material with high thermal conductivity such as a metal, including an alloy or epoxy, comprising Ag (e.g., greater than or equal to 80 wt. %), In (e.g., 99 wt. %, or as much as 99.99 wt. %), AgIn (e.g., 90 wt. % In and 10 wt. % Ag), AgIn₂, AuIn, AuIn₂, InₓNi_{y}Au, InₓNi_{y}Ag, other materials such as silicon, ceramic, heat conductive glass, copper, iron, combinations or alloys thereof, or the like. The thermal interface material TIM may also be referred to as a heat dissipation die, a heat dissipation feature, a dummy die, or a thermal enhancement die.

In some embodiments, an adhesive layer 116 is disposed between a bottom RPb of the ring portion RP of the lid structure 106 and the top surface 102s of the package substrate 102. The adhesive layer 116 may be any suitable non-conductive adhesive, epoxy, die attach film (DAF), or the like, and may be applied to the bottom RPb of the ring portion RP or may be applied over the top surface 102s of the package substrate 102 before installing the lid structure 106. In some embodiments, other adhesive layers (not specifically illustrated) along a bottom surface LPb of the lid portion LP may be used to improve attachment of the lid structure 106 to the thermal interface material TIM. In some embodiments (not specifically illustrated), the integrally-formed ring portion RP, lid portion LP and the vapor chamber VC are first formed over or attached to the package substrate 102, and the upper cover UC is subsequently attached to the vapor chamber VC to form the lid structure 106 using an adhesive or any suitable method.

In some embodiments, an underfill 118 may be formed around the chip 104. The underfill 118 may reduce stress and protect the joints resulting from the reflowing of the chip 104. The underfill 118 may be formed of an underfill material such as a molding compound, a resin (e.g., epoxy resin), a filler material, a stress release agent (SRA), an adhesion promoter, other material, or a combination thereof. The underfill 118 may be formed by a capillary flow process after the chip 104 is attached to the top surface 102s of the package substrate 102, or may be formed by a suitable deposition method after the chip 104 is attached to the top surface 102s of the package substrate 102. The underfill 118 may be applied in liquid or semi-liquid form and then subsequently cured. In some embodiments, the underfill is optional.

FIG. 2 illustrates a three-dimensional view of a lid structure of the package structure in accordance with some embodiments of the present disclosure. For example, the three-dimensional view of the lid structure 106 in FIG. 1 is as exemplarily shown in FIG. 2.

Referring to FIG. 2, the lid structure 200 may include a ring portion RP, a lid portion LP, a vapor chamber VC, and an upper cover UC. In some embodiments, the ring potion RP, the lid portion LP and the vapor chamber VC are integrally formed with a single material. In FIG. 2, a continuous trench T2 is formed in the upper cover UC and extends from the top surface UCt. The size and location of the continuous trench T2 are similar to the trench T1 as described in FIG. 1, and thus the details thereof are not repeated herein for brevity. In some embodiments, columns 202 are arranged in the vapor chamber VC, and the column 202 is a cylinder. However, it is not limited thereto; in some embodiments, the column 202 may be a ball, a cube, or the like.

FIGS. 3A and 3B are top views of a lid structure of the package structure according to embodiments of the present disclosure, wherein portions of the lid structure (e.g. the lid portion and the vapor chamber) are omitted for brevity.

In FIG. 3A, the trench T3a in the upper cover UC is a continuous trench, and the trench T3a in the upper cover UC is directly over the ring portion RP of the lid structure 300a. The trench T3a is straight.

In FIG. 3B, the trench T3b in the upper cover UC is a continuous trench, and the trench T3b in the upper cover UC is partially overlapped with the ring portion RP of the lid structure 300b. The trench T3b is straight.

FIGS. 4A and 4B are top views of a lid structure of the package structure according to embodiments of the present disclosure, wherein portions of the lid structure (e.g. the lid portion and the vapor chamber) are omitted for brevity.

In FIG. 4A, the trench in the upper cover UC of the lid structure 400a is composed of a plurality of discontinuous trenches T4a. The trenches T4a are directly over the ring portion RP.

In FIG. 4B, the trench T4b in the upper cover UC of the lid structure 400b is a continuous trench. The trench T4b is directly over the ring portion RP. The trench T4b is wavy.

As the configuration of the at least one trench can be adjusted, there will be different degrees of weak for the lid structure so as to let higher warpage substitutes the adhesive delamination risk. In sum, it is possible that the shape, the size, the location, and the relative positions to other portions of the at least one trench may be changed depending on the stress on the lid structure.

FIG. 5 illustrates a cross-sectional view of a package structure in accordance with some embodiments of the present disclosure. The package structure 500 in this embodiment is similar to the package structure 100 shown in FIG. 1, except that the detail of the lid structure 106.

Referring to FIG. 5, the package structure 500 includes the package substrate 102, the chip 104, and the lid structure 106. The lid structure 106 includes the ring portion RP, the lid portion LP, the vapor chamber VC, and the upper cover UC. The lid portion LP is disposed over the chip 104. The ring portion RP surrounds the lid portion LP and disposed on the package substrate 102 to encapsulate the chip 104; accordingly, side surfaces LPs of the lid portion LP are in direct contact with inner sidewalls RPi of the ring portion RP. The vapor chamber VC is disposed on the lid portion LP. The upper cover UC is disposed over the vapor chamber VC. At least one trench T5 is formed in the ring portion RP and extends from outer sidewalls RPs of the ring portion RP. In some embodiments, the trench T5 is aligned with the lid portion LP to release stress from the vapor chamber VC and the upper cover UC. In some embodiments, the trench T5 may be a continuous trench or a plurality of discontinuous trenches.

In some embodiments, a ratio of a depth d2 of the trench T5 to a width w3 of the ring portion RP is in a range from 0.4 to 0.6. In some embodiments, a lower limit of the ratio of the depth d2 to the width w3 is 0.42, 0.45, and so on. In some embodiments, an upper limit of the ratio of the depth d2 to the width w3 is 0.58, 0.56, and so on.

In some embodiments, a ratio of a width w4 of the trench T5 to a height h1 of the ring portion RP is in a range from 0.2 to 0.8. In some embodiments, a lower limit of the ratio of the width w4 to the height h1 is 0.25, 0.3, 0.35, 0.4, and so on. In some embodiments, an upper limit of the ratio of the width w4 to the height h1 is 0.75, 0.7, 0.65, 0.6, and so on.

FIG. 6 illustrates a three-dimensional view of a lid structure of the package structure in accordance with some embodiments of the present disclosure. For example, the three-dimensional view of the lid structure 106 in FIG. 5 is as exemplarily shown in FIG. 6.

Referring to FIG. 6, the lid structure 600 may include a ring portion RP, a lid portion LP, a vapor chamber VC, and an upper cover UC. In some embodiments, the ring potion RP, the lid portion LP and the vapor chamber VC are integrally formed with a single material. In FIG. 6, a continuous trench T6 is formed in the ring portion RP and extends from the outer sidewalls RPs. The size and location of the continuous trench T6 are similar to the trench T5 as described in FIG. 5, and thus the details thereof are not repeated herein for brevity. In some embodiments, columns 202 are arranged in the vapor chamber VC, and the column 202 is a cylinder. However, it is not limited thereto; in some embodiments, the column 202 may be a ball, a cube, or the like.

FIG. 7 illustrates a cross-sectional view of a package structure in accordance with some embodiments of the present disclosure. The package structure 700 in this embodiment is similar to the package structure 500 shown in FIG. 5, except that the location and the size of the trench T7.

In FIG. 7, the trench T7 is vertically offset from the lid portion LP. That is, the position of the trench T7 is shifted toward the package substrate 102, and the trench T7 is not connected to the vapor chamber VC. In some embodiments, a width w5 of the trench T7 may be wider than the width w4 of the trench T5 of FIG. 5.

FIGS. 8A and 8B illustrate side views of a lid structure of the package structure according to embodiments of the present disclosure.

In FIG. 8A, the trench in the ring portion RP of the lid structure 800a is composed of a plurality of discontinuous trenches T8a. The trenches T8a are all straight trenches.

In FIG. 8B, the trench in the ring portion RP of the lid structure 800b is also composed of a plurality of discontinuous trenches T8b, and the trenches T8b are all wavy trenches.

According to results of simulation experiments, in case of other components of the package structure being the same, the lid structure 200 of FIG. 2 can reduce the adhesive delamination risk, and the lid structure 600 of FIG. 6 can also reduce the adhesive delamination risk.

FIG. 9 illustrates a three-dimensional view of a lid structure of the package structure in accordance with some embodiments of the present disclosure.

Referring now to FIG. 9, the lid structure 900 has the trench T2 as described in FIG. 2 and the trench T6 as described in FIG. 6. Therefore, in the lid structure 900, the trench T1 is formed in the upper cover UC and extends from the top surface UCt, and the trench T6 is formed in the ring portion RP and extends from the outer sidewalls RPs. The size and location of the continuous trench T6 are similar to the trench T5 as described in FIG. 5, and thus the details thereof are not repeated herein for brevity. The size and location of the continuous trench T2 are similar to the trench T1 as described in FIG. 1, and thus the details thereof are not repeated herein for brevity.

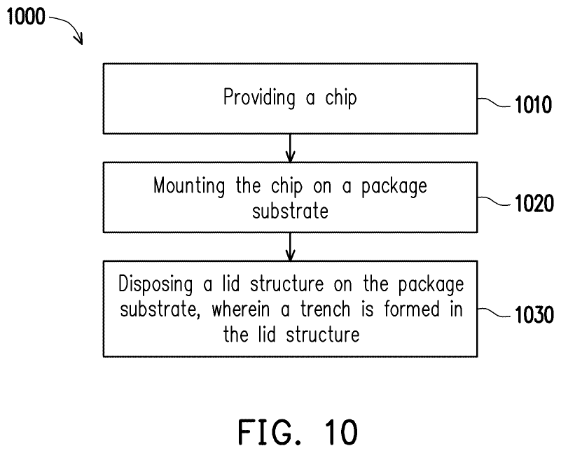

FIG. 10 is a flowchart illustrating a method for forming a package structure in accordance with some embodiments of the present disclosure.

Referring now to FIG. 10, a flowchart illustrates a method 1000 for forming a package structure. The method 1000 includes a step 1010 to provide a chip. In some embodiments, the chip may be a CoW wafer which is bonded to the package substrate 102. In some embodiments, the chip may be an integrated circuit die such as a logic device (e.g., CPU, GPU, microcontroller, etc.), a memory device (e.g., DRAM die, SRAM die, etc.), a power management device (e.g., PMIC die), a RF device, a sensor device, a MEMS device, a signal processing device (e.g., DSP die), a front-end device (e.g., AFE dies), the like, or a combination thereof (e.g., SoC die). In some embodiments, the chip may include a semiconductor substrate, an interconnect structure, die connectors, and the like.

The method 1000 includes a step 1020 to mount the chip on a package substrate. In some embodiments, the package substrate is a printed circuit board (PCB) or the like. In some embodiments, the package substrate is referred to as a circuit substrate. In some embodiments, the package substrate includes a plurality of routing patterns (not shown) embedded therein, and the routing patterns are interconnected with one another. That is, the routing patterns are electrically connected to one another. In some embodiments, some of the routing patterns are exposed at the surface on which the chip is mounted. In some embodiments, the chip is mounted on the package substrate through conductive terminals. For example, the conductive terminals of the chip are in physical contact with the exposed routing patterns to render electrical connection between the chip and the package substrate. In some embodiments, after the conductive terminals are attached to the routing patterns of the package substrate, a reflow process may be performed to reshape the conductive terminals. In some embodiments, the package substrate includes a substrate core (not shown), which may be made of a semiconductor material such as silicon, germanium, diamond, or the like; a compound material such as silicon germanium, silicon carbide, gallium arsenic, indium arsenide, indium phosphide, silicon germanium carbide, gallium arsenic phosphide, gallium indium phosphide, combinations thereof, or the like. In addition, the substrate core may be a SOI substrate or an insulating core such as a fiberglass reinforced resin core. Alternatives for the core material include BT resin, or the like. Build up films such as ABF or other laminates may be used for the substrate core. In some embodiments, the substrate core of the package substrate may also include metallization layers and vias, and bond pads over the metallization layers and vias.

In some embodiments, an underfill may be formed between the chip and the surface of the package substrate after the step 1020. For example, the underfill wraps around the conductive terminals of the chip. In some embodiments, the underfill may be formed by a capillary flow process after the step 1020. In some embodiments, the underfill further covers portions of each sidewall of the chip. In some embodiments, a material of the underfill includes a molding compound, a resin (e.g., epoxy resin), a filler material, a SRA, an adhesion promoter, other material, or a combination thereof. In some embodiments, the underfill is optional.

The method 1000 includes a step 1030 to dispose a lid structure on the package substrate, wherein a trench is formed in the lid structure. The chip is located in a space confined between the lid structure and the package substrate. The lid structure may serve as the heat spreading portion of the package structure, and the lid structure may be any of the lid structure shown in above figures. That is, the lid structure comprises a ring portion surrounding the chip, a lid portion disposed on the ring portion, a vapor chamber disposed on the lid portion, and an upper cover over the vapor chamber, wherein at least one trench is disposed in the upper cover extending from a top surface of the upper cover (as shown in FIG. 2) or in the ring portion extending from outer sidewalls of the ring portion (as shown in FIG. 6). In some embodiments, before the step 1030, the method 1000 may further include a step of forming an adhesive layer between the ring portion of the lid structure and the package substrate. In some embodiments, the lid structure is placed on the package substrate and held in place using the adhesive layer interposed between a bottom of the ring potion and a top surface of the package substrate. The adhesive layer may be any suitable non-conductive adhesive, epoxy, DAF, or the like.

It is understood that additional steps may be performed before, during, or after the steps 1010-1030. For example, before the step 1030, the method 1000 may further include a step of forming a thermal interface material between the lid portion of the lid structure and a top of the chip. In some embodiments, the thermal interface material is formed on the top of the chip through a dispensing process, or as a pre-formed film that is laminated on the top of the chip. In some embodiments, a material of the thermal interface material includes a metal, including an alloy or epoxy, comprising Ag (e.g., greater than or equal to 80 wt. %), In (e.g., 99 wt. %, or as much as 99.99 wt. %), AgIn (e.g., 90 wt. % In and 10 wt. % Ag), AgIn₂, AuIn, AuIn₂, InₓNi_{y}Au, InₓNi_{y}Ag, other materials such as silicon, ceramic, heat conductive glass, copper, iron, combinations or alloys thereof, or the like.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a package structure includes a package substrate, a chip, and a lid structure. The chip is disposed on the package substrate, and the lid structure is disposed over the chip and bonded to the package substrate. The lid structure includes a ring portion, a lid portion, a vapor chamber, and an upper cover. The ring portion surrounds the chip. The lid portion is disposed on the ring portion to encapsulate the chip. The vapor chamber is disposed on the lid portion. The upper cover is disposed over the vapor chamber. At least one trench is formed in the upper cover and extends from a top surface of the upper cover.

According to some embodiments, a package structure includes a package substrate, a chip, and a lid structure. The chip is disposed on the package substrate, and the lid structure is disposed over the chip and bonded to the package substrate. The lid structure includes a ring portion, a lid portion, a vapor chamber, and an upper cover. The lid portion is disposed over the chip. The ring portion surrounds the lid portion and disposed on the package substrate to encapsulate the chip. The vapor chamber is disposed on the lid portion. The upper cover is disposed over the vapor chamber. At least one trench is formed in the ring portion and extends from outer sidewalls of the ring portion.

According to some embodiments, a method for forming a semiconductor package includes providing a chip, mounting the chip on a package substrate, and disposing a lid structure on the package substrate, the chip being located in a space confined between the lid structure and the package substrate, wherein the lid structure comprises a ring portion surrounding the chip, a lid portion disposed on the ring portion, a vapor chamber disposed on the lid portion, and an upper cover over the vapor chamber, wherein at least one trench is disposed in the upper cover extending from a top surface of the upper cover or in the ring portion extending from outer sidewalls of the ring portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a chip, disposed on the package substrate; and
a lid structure, disposed over the chip and bonded to the package substrate, wherein the lid structure comprises:
a ring portion, surrounding the chip;
a lid portion, disposed on the ring portion to encapsulate the chip;
a vapor chamber, disposed on the lid portion; and
an upper cover, disposed over the vapor chamber, wherein at least one trench is formed in the upper cover and extends from a top surface of the upper cover.

2. The package structure according to claim 1, wherein the at least one trench is directly over the ring portion of the lid structure.

3. The package structure according to claim 1, wherein in a top view, the at least one trench is partially overlapped with the ring portion of the lid structure.

4. The package structure according to claim 1, wherein a fluid is contained in the vapor chamber of the lid structure.

5. The package structure according to claim 1, wherein the at least one trench is a continuous trench or a plurality of discontinuous trenches.

6. The package structure according to claim 1, wherein in a top view, the at least one trench is straight or wavy.

7. The package structure according to claim 1, wherein a ratio of a depth of the at least one trench to a thickness of the upper cover is in a range from 0.5 to 1.

8. The package structure according to claim 1, wherein a ratio of a width of the at least one trench to a width of the upper cover is in a range from 0.05 to 0.3.

9. A package structure, comprising:
a package substrate;
a chip, disposed on the package substrate; and
a lid structure, disposed over the chip and attached to the package substrate, wherein the lid structure comprises:
a lid portion, disposed over the chip;
a ring portion, surrounding the lid portion and disposed on the package substrate to encapsulate the chip;
a vapor chamber, disposed on the lid portion; and
an upper cover over the vapor chamber, wherein at least one trench is formed in the ring portion and extends from outer sidewalls of the ring portion.

10. The package structure according to claim 9, wherein the at least one trench is aligned with the lid portion.

11. The package structure according to claim 9, wherein the at least one trench is vertically offset from the lid portion.

12. The package structure according to claim 9, wherein a fluid is contained in the vapor chamber of the lid structure.

13. The package structure according to claim 9, wherein the at least one trench is a continuous trench or a plurality of discontinuous trenches.

14. The package structure according to claim 9, wherein in a top view, the at least one trench is straight or wavy.

15. The package structure according to claim 9, wherein a ratio of a depth of the at least one trench to a width of the ring portion is in a range from 0.4 to 0.6.

16. The package structure according to claim 9, wherein a ratio of a width of the at least one trench to a height of the ring portion is in a range from 0.2 to 0.8.

17. A method for forming a semiconductor package, comprising:
providing a chip;
mounting the chip on a package substrate; and
disposing a lid structure on the package substrate, the chip being located in a space confined between the lid structure and the package substrate, wherein the lid structure comprises a ring portion surrounding the chip, a lid portion disposed on the ring portion, a vapor chamber disposed on the lid portion, and an upper cover over the vapor chamber, wherein at least one trench is disposed in the upper cover extending from a top surface of the upper cover or in the ring portion extending from outer sidewalls of the ring portion.

18. The method for forming a semiconductor package according to claim 16, wherein the ring potion, the lid portion and the vapor chamber are integrally formed with a single material.

19. The method for forming a semiconductor package according to claim 16, wherein before disposing the lid structure, further comprising forming a thermal interface material between the lid portion of the lid structure and a top of the chip.

20. The method for forming a semiconductor package according to claim 16, before disposing the lid structure, further comprising forming an adhesive layer between the ring portion of the lid structure and the package substrate.
